(19) United States
(12) Patent Application Publication
(10) Pub. No.: US 2026/0112585 A1
(43) Pub. Date: Apr. 23, 2026

(54) SELF-COMPLIANT SEAL ASSEMBLY

(71) Applicant: Applied Materials, Inc., Santa Clara, CA (US)

(72) Inventors: Tuan Anh NGUYEN, San Jose, CA (US); Vishwas BASAVARAJAIAH SOMASHEKAR, Bangalore (IN); Samir NAYFEH, Santa Clara, CA (US)

(21) Appl. No.: 19/350,499

(22) Filed: Oct. 6, 2025

Related U.S. Application Data
(60) Provisional application No. 63/709,128, filed on Oct. 18, 2024.

(51) Int. Cl. H01J 37/32; C23C 16/458; C23C 16/509

(52) U.S. Cl. CPC H01J 37/32715; C23C 16/4583; C23C 16/509; H01J 37/32513; H01J 2237/2005; H01J 2237/3321

(57) ABSTRACT

A process station is provided. The process station includes a chamber body defining a chamber volume. The process station also includes a pumping plate disposed in the chamber body. Further, the process station includes a substrate support disposed in the chamber body. The substrate support includes a seal plate and a self-compliant seal assembly. The self-compliant seal assembly includes a compliant diaphragm having an inner rim and an outer rim, the inner rim being coupled with the seal plate and the outer rim forming a cavity; a spring element disposed in the cavity; and a compliant sheet disposed between the seal plate and the inner rim and between the outer rim and the pumping plate. The spring element is arranged to bias the compliant sheet toward the pumping plate to form a compliant seal that isolates a first region from a second region of the chamber volume.

### CROSS-REFERENCE TO RELATED APPLICATIONS

This application claims benefit of US Provisional application number 63/709,128, filed October 18, 2024, which is incorporated herein by reference in its entirety.

### BACKGROUND

### Field

Embodiments of the present disclosure generally relate to a substrate support design for a substrate processing chamber, such as is used in semiconductor processing or the like.

### Description of the Related Art

Substrate processing chambers, such as those used in semiconductor processing or the like, typically have a substrate support that can be moved vertically between a lowered position and a raised position. The substrate support is moved to the lowered position to facilitate the transfer of a substrate into, and out of, the processing chamber. The substrate support is moved to the raised position to facilitate the processing of a substrate disposed thereon. In some processing chambers, the substrate support includes a support plate and a seal plate. The support plate includes a support surface on which a substrate is disposed during processing. The seal plate is configured to form a seal with another chamber component, such as a liner assembly, when the substrate support is in the raised position. The seal plate can thus be used to isolate a processing region of the processing chamber from the rest of the processing chamber during processing.

In some processing chambers, when the substrate support is in a raised position (e.g., a processing position), the substrate and a showerhead of the processing chamber can be misaligned. For example, the substrate might not be parallel with the showerhead because the support surface of the substrate support is not parallel with the showerhead. Such misalignment can result in uneven processing of the substrate, which can adversely affect product quality and yield.

In some processing chambers, when the substrate support is in the raised position, the seal between the seal plate and a chamber component can be compromised by misalignment of the seal plate with respect to the chamber component. The compromised seal can result in processing gases escaping from the processing region and the deposition of contaminants in various regions of the processing chamber. Moreover, the element forming the seal is typically temperature limiting.

Accordingly, there is a need for improved systems that address one or more of the challenges described above.

### SUMMARY

The present disclosure generally relates to a self-compliant seal assembly to facilitate formation of a seal despite a misalignment of a seal plate relative to another component. The self-compliant seal can also enable a symmetric/uniform radio frequency (RF) return current path to one or more RF generators/match.

In one aspect, a process station is provided. The process station includes a chamber body defining a chamber volume. The process station also includes a pumping plate disposed in the chamber body. Further, the process station includes a substrate support disposed in the chamber body. The substrate support includes a seal plate and a self-compliant seal assembly. The self-compliant seal assembly includes a compliant diaphragm having an inner rim and an outer rim, the inner rim being coupled with the seal plate and the outer rim forming a cavity; a spring element disposed in the cavity; and a compliant sheet disposed between the seal plate and the inner rim and between the outer rim and the pumping plate. The spring element is arranged to bias the compliant sheet toward the pumping plate to form a compliant seal that isolates a first region from a second region of the chamber volume.

In another aspect, a process station is provided. The process station includes a radio frequency (RF) generator, a chamber body defining a chamber volume, a pumping plate disposed in the chamber body, and a substrate support disposed in the chamber body. The substrate support includes a seal plate and a self-compliant seal assembly. The self-compliant seal assembly includes a compliant diaphragm having an inner rim and an outer rim, the inner rim being coupled with the seal plate and the outer rim forming a cavity. Further, the self-compliant seal assembly includes a spring element disposed in the cavity and a compliant sheet disposed between the seal plate and the inner rim and between the outer rim and the pumping plate. The spring element is arranged to bias the compliant sheet toward the pumping plate to form a compliant seal that isolates a first region from a second region of the chamber volume and forms a symmetric RF return path to the RF generator.

In yet another aspect, a self-compliant seal assembly for a process station is provided. The self-compliant seal assembly includes a compliant diaphragm having an inner rim, an outer rim, and a base wall extending between and connecting the inner rim and the outer rim. The outer rim defines a cavity. A diaphragm channel is defined between the inner rim and the outer rim. The self-compliant seal assembly also includes a spring element disposed in the cavity. In addition, the self-compliant seal assembly includes a compliant sheet contacting the inner rim and the outer rim, wherein the compliant sheet encloses the diaphragm channel and the spring element within the cavity.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1A is a schematic view of a processing chamber in which a substrate support is in a lowered position, according to one or more embodiments disclosed herein.

FIG. 1B is a schematic view of the processing chamber of FIG. 1A in which the substrate support is in a raised position for the processing of a substrate, according to one or more embodiments disclosed herein.

FIG. 2A illustrates a close-up, schematic cross-sectional view of a portion of a processing chamber, according to one or more embodiments disclosed herein.

FIG. 2B illustrates a close-up, schematic cross-sectional view of a self-compliant seal assembly of a processing chamber, according to one or more embodiments disclosed herein.

FIG. 2C illustrates a close-up, schematic cross-sectional view of another self-compliant seal assembly of a processing chamber, according to one or more embodiments disclosed herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to a substrate support assembly used in a substrate processing chamber that includes a self-compliant seal assembly configured to isolate a first region of the processing chamber from a second region of the processing chamber during the processing of a substrate. In some embodiments, the self-compliant seal assembly can facilitate the maintaining of a seal between a seal plate of a substrate support and another chamber component, such as a liner assembly, despite the seal plate being misaligned with the chamber component. In addition to the self-compliant seal assembly maintaining the seal, the self-compliant seal assembly can provide a symmetric radio frequency (RF) return current path to the generators, which can lead to better process performance.

In one example aspect, a process station is provided. The process station can include a chamber body defining a chamber volume. The process station can also include a pumping plate disposed in the chamber body. Further, the process station can include a substrate support disposed in the chamber body. The substrate support can include a support plate and a seal plate arranged below the support plate. A substrate can be disposed on the support plate. The substrate support can also include a self-compliant seal assembly. The self-compliant seal assembly can include a compliant diaphragm, a spring element, and a compliant sheet. The compliant diaphragm can have an inner rim and an outer rim. The inner rim can be coupled with the seal plate and the outer rim can form a cavity. The spring element can be disposed in the cavity. An inner portion of the compliant sheet can be disposed between the seal plate and the inner rim and an outer portion of the compliant sheet can be disposed between the outer rim and the pumping plate. The spring element is arranged to bias the compliant sheet toward the pumping plate to form a compliant seal that isolates a first region from a second region of the chamber volume. Specifically, the spring element can apply a force on the compliant sheet to “form” or “mold” the compliant sheet to any undulations in the pumping plate, which can create an annular line contact for obtaining the compliant seal in the chamber-in-chamber architecture.

Further, the compliant diaphragm can facilitate the sealing engagement of the compliant sheet with the pumping plate by providing the assembly the flexibility to account for misalignment of the seal plate with the pumping plate. The compliant diaphragm can also allow for the sealing engagement of the compliant sheet with the pumping plate to be made for a wide range of distances between the support plate and a showerhead in the processing region. Stated another way, the flexible and compliant nature of the compliant diaphragm can enable the capability to tune the spacing and adjust the level of the support plate independently of the seal plate. Moreover, in some embodiments, the components of the self-compliant seal assembly can be formed of relatively high temperature-resistant materials, e.g., materials able to withstand at least three hundred degrees Celsius (300° C). In this way, higher operating temperature applications can be achieved.

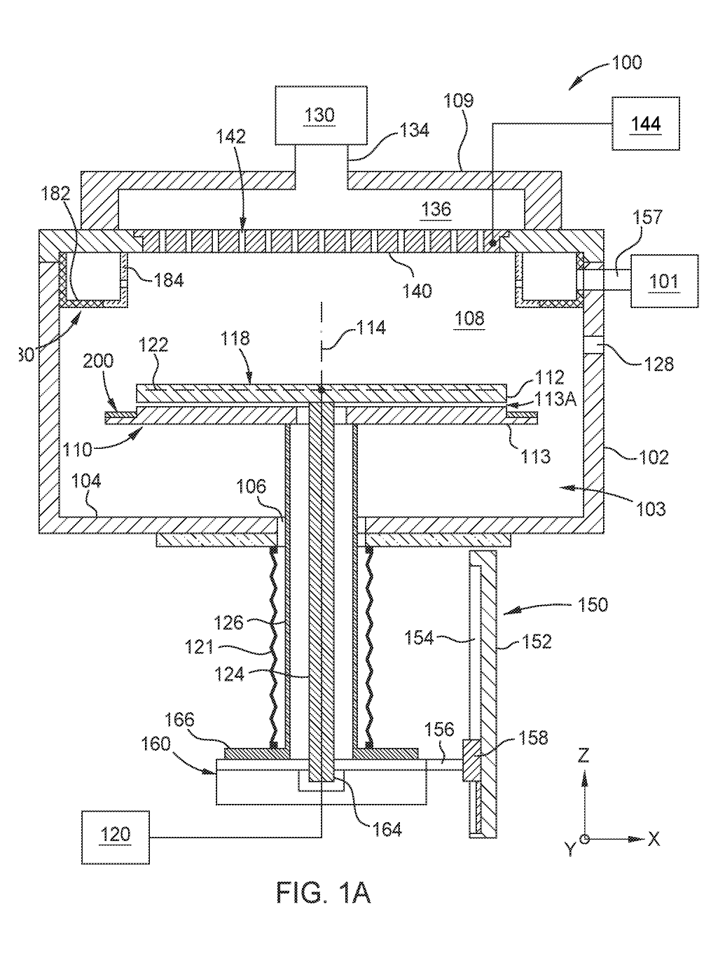

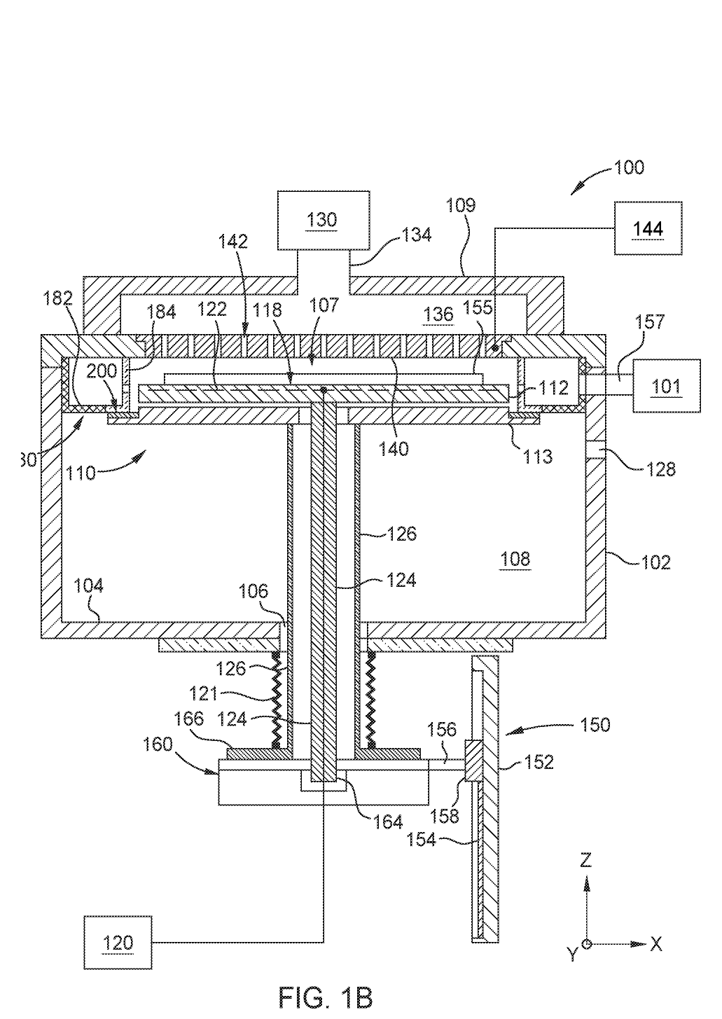

FIGS. 1A and 1B are schematic cross-sectional views of a processing chamber 100. In general, the processing chamber 100 can include an atomic layer deposition (ALD) chamber, chemical vapor deposition (CVD) chamber, physical vapor deposition (PVD) chamber, etch chamber, degas chamber, an ion implantation chamber, ashing chamber, cleaning chamber, a thermal processing chamber (e.g., rapid thermal processing, anneal, cool down, thermal management control), or other type of substrate processing chamber.

However, as illustrated in FIGS. 1A and 1B, the processing chamber 100 is configured as a Plasma Enhanced Chemical Vapor Deposition (“PECVD”) chamber. Nevertheless, the processing chamber 100 may be configured to perform one or more other processing operations that may or may not involve a plasma. The processing chamber 100 may include relevant hardware associated with any of the above processes.

The processing chamber 100 includes a chamber body 102 with a floor 104, a substrate support 110 disposed inside the chamber body 102, and a lid 109 coupled to the chamber body 102. The chamber body 102 defines a chamber volume 103. FIG. 1A shows the substrate support 110 in a lowered position, such as when a substrate is transferred into or out of the processing chamber 100. FIG. 1B shows the substrate support 110 in a raised position (e.g., a processing position), such as when a substrate is being processed. In the raised position, a seal plate 113 engages another component, such as a liner assembly 180, to form a first region 107 (e.g., a processing region) where the substrate processing is performed. While the seal plate 113 is in the raised position, as shown in FIG. 1B, the first region 107 is isolated from a second region 108, which is the surrounding open volume of the chamber volume 103. In some embodiments, the processing chamber 100 includes a showerhead 140 that introduces gases into the first region 107. In some of such embodiments, the showerhead 140 can serve as an electrode, and is coupled to a power source 144 through a match circuit (not shown). The power source 144 is a radio frequency (RF) power source that is electrically coupled to the electrode. Further, the power source 144 provides between about 100 Watts and about 3,000 Watts at a frequency of about 50 kHz to about 15 MHz. In some embodiments, the power source 144 can be pulsed during various operations. The electrode and power source 144 facilitate control of a plasma formed within the first region 107.

The showerhead 140 features openings 142 for admitting a process gas or gases into the first region 107 from a gas supply source 130. The process gases are supplied to the processing chamber 100 via a gas feed 134, and the process gases enter a plenum 136 prior to flowing through the openings 142. In some embodiments, different process gases that are delivered simultaneously during a processing operation enter the processing chamber 100 via separate gas feeds and separate plenums prior to entering the first region 107 through the showerhead 140.

The gas supply source 130 includes one or more gas sources. The gas supply source 130 is configured to deliver the one or more gases from the one or more gas sources through the showerhead 140 and into the first region 107. Each of the one or more gas sources provides a process gas such as silane, disilane, tetraethyl orthosilicate (TEOS), germane, a metal halide (such as titanium tetrachloride, tantalum pentachloride, tungsten hexafluoride), an organometallic (such as tetrakis(dimethylamido) titanium, pentakis(dimethylamido) tantalum), ammonia, oxygen (O₂), hydrogen peroxide, hydrogen (H₂), diborane, chlorine (Cl₂), sulfur hexafluoride, argon (Ar), helium (He), nitrogen (N₂), and a hydrocarbon (generically CₓH_{y}), among others. In some embodiments, the process gas may be ionized to form a plasma within the first region 107. In an example, one or more of a carrier gas and an ionizable process gas are provided into the first region 107 to process a substrate 155 (FIG. 1B). For instance, when processing a 300 mm substrate, the process gases are introduced to the processing chamber 100 at a flow rate from about 6500 sccm to about 8000 sccm, from about 100 sccm to about 10,000 sccm, or from about 100 sccm to about 1000 sccm. Alternatively, other flow rates may be utilized. In some examples, a remote plasma source can be used to deliver plasma to the processing chamber 100 and can be coupled to the gas supply source 130.

In some embodiments, the processing chamber 100 includes a physical vapor deposition (PVD) target, which is similarly positioned as the showerhead 140 illustrated in FIGS. 1A and 1B, and thus takes the place of the showerhead 140. In such a configuration, the PVD target serves as a sputtering material source, and is coupled to the power source 144, which is typically a DC power source. The DC power source is adapted to provide a DC voltage at a power level that is typically greater than 1 kW. A magnetron (e.g., a magnet assembly not shown) is positioned behind the PVD target and is used to help control the gas ion bombardment of the lower surface of the target during processing to allow for uniform erosion (e.g., sputtering) of the target surface during processing.

In some embodiments, the processing chamber 100 includes the liner assembly 180. In some embodiments, the liner assembly 180 includes one or more liners 182. In some embodiments, the liner assembly 180 includes a pumping plate 184. Process gases flow into the first region 107 through the showerhead 140, then exit the first region 107 via the liner assembly 180. The process gases flow from the liner assembly 180 through an exhaust port 157 coupled to a vacuum pump 101. The vacuum pump 101 removes excess process gases or by-products from the first region 107 via the exhaust port 157 during and/or after processing the substrate 155.

The substrate 155 is provided to the first region 107 through an opening 128. In an example, the substrate 155 is transported into or out of the first region 107 using a carrier, such as a blade, that is conveyed by a robotic arm, such as a linear swapper.

In either or any of the various possible processing chamber configurations, the substrate support 110 includes a support plate 112 that includes a support surface 118 configured to support the substrate 155 in the first region 107 of the processing chamber 100 during processing. In some embodiments that may be combined with other embodiments, the support plate 112 is coupled to the seal plate 113. In some embodiments, the support plate 112 can be rigidly coupled with the seal plate 113, e.g., so that the support plate 112 and the seal plate 113 are not movable relative to one another. In some examples, a lower surface of the support plate 112 is coupled to an upper surface of the seal plate 113. As illustrated, in other examples, the lower surface of the support plate 112 and the upper surface of the seal plate 113 are separated by a gap 113A (FIG. 1A). In some embodiments that may be combined with other embodiments, the seal plate 113 is present, but is not coupled directly to the support plate 112.

The support plate 112 contains, or is formed from, one or more metallic or ceramic materials. Exemplary metallic or ceramic materials include one or more metals, metal oxides, metal nitrides, metal oxynitrides, or any combination thereof. For example, the support plate 112 may contain or be formed from aluminum, aluminum oxide, aluminum nitride, aluminum oxynitride, boron nitride, or any combination thereof.

As illustrated, a heater or electrode 122 is embedded within the support plate 112, but alternatively may be coupled to a surface (such as the support surface 118) of the support plate 112. The electrode 122 is coupled to a power source 120. It is contemplated that the power source 120 may supply DC power, pulsed DC power, radio frequency (RF) power, pulsed RF power, or any combination thereof. The power source 120 is configured to drive the electrode 122 with a drive signal to generate a plasma within the first region 107. It is contemplated that the drive signal may be one of a DC signal and a varying voltage signal (e.g., an RF signal). Further, the electrode 122 may alternatively be coupled to the power source 144 instead of the power source 120, and the power source 120 may be omitted.

In some embodiments that may be combined with other embodiments, the electrode 122 may be omitted. In some embodiments that may be combined with other embodiments, the electrode 122 (or another electrode in the support plate 112) is configured as a chucking electrode. In some embodiments that may be combined with other embodiments, the support plate 112 includes a heater, such as a resistive heating element. In some embodiments that may be combined with other embodiments, the substrate support 110 includes one or more coolant channels.

The support plate 112 is disposed on a first support shaft 124 that extends through an aperture 106 in the floor 104 of the processing chamber 100. In some embodiments that may be combined with other embodiments, the support plate 112 is rotated about a central axis 114 by a drive mechanism (not shown) coupled to the first support shaft 124 while the substrate 155 is undergoing processing in the processing chamber 100. Movement of the first support shaft 124 (e.g., along the Z axis) raises or lowers the support plate 112 such that the support surface 118 is moved towards or away from the showerhead 140 (or the PVD target, if present).

The seal plate 113 is disposed on a second support shaft 126 that extends through the aperture 106 in the floor 104 of the processing chamber 100. The first support shaft 124 is disposed through the second support shaft 126. Movement of the second support shaft 126 (e.g., along the Z axis) raises or lowers the seal plate 113.

The first support shaft 124 and the second support shaft 126 are coupled to a base 160. The base 160 is coupled to an actuator assembly 150 that raises and lowers (e.g., along the Z axis) the base 160, and thus raises and lowers the first support shaft 124 and the second support shaft 126, and so raises and lowers the support plate 112 and the seal plate 113.

The actuator assembly 150 may include a lift guide 152 and a carriage 158. The lift guide 152 includes a guide channel 154. The carriage 158 is movable along the lift guide 152. A carrier plate 156 is coupled to the carriage 158, which is movable along the guide channel 154. An actuator, such as a piston or a linear motor, moves the carriage 158 along the guide channel 154. Movement of the carriage 158 (e.g., along the Z axis) along the guide channel 154 moves the carrier plate 156 along the lift guide 152 between a lowered position and a raised position.

The second support shaft 126 is coupled to the carrier plate 156. In some embodiments that may be combined with other embodiments, the second support shaft 126 is coupled to the carrier plate 156 via a seal plate hub 166 (e.g., cooling hub) that is coupled to the second support shaft 126. In an example, the seal plate hub 166 provides connections for the passage of a coolant to and from the seal plate 113. The seal plate hub 166 is coupled to an upper surface of the carrier plate 156, such as by bolts.

The carrier plate 156 includes an aperture through which the first support shaft 124 extends. The first support shaft 124 is coupled to a support plate hub 164. In an example, the support plate hub 164 provides connections for the passage of a coolant to and from the support plate 112. The support plate hub 164 is disposed below the seal plate hub 166 and below the carrier plate 156.

Movement of the carrier plate 156 along the lift guide 152 between a lowered position and a raised position moves the seal plate hub 166, the second support shaft 126, the seal plate 113, the support plate hub 164, the first support shaft 124, and the support plate 112 between lowered and raised positions.

In some embodiments that may be combined with other embodiments, a bellows 121 surrounds the second support shaft 126 and extends between the seal plate hub 166 and the floor 104 of the processing chamber 100. In some embodiments that may be combined with other embodiments, the bellows 121 surrounds the first support shaft 124 and extends between the support plate hub 164 and the carrier plate 156. The bellows 121 provides isolation of the environment within the processing chamber 100 from the ambient environment external to the processing chamber 100.

As further shown in FIGS. 1A and 1B, the substrate support 110 includes a self-compliant seal assembly 200 (illustrated schematically in FIGS. 1A and 1B). The self-compliant seal assembly 200 is coupled with the seal plate 113, and when the substrate support 110 is in the raised position, e.g., as shown in FIG. 1B, at least one component of the self-compliant seal assembly 200 engages the pumping plate 184 to facilitate sealing of the first region 107 from the second region 108, or rather, to create a tortious path for gases so that a leak rate from one region to another is under a predefined threshold, such as 200 mtorr/min. The self-compliant seal assembly 200 is further described below.

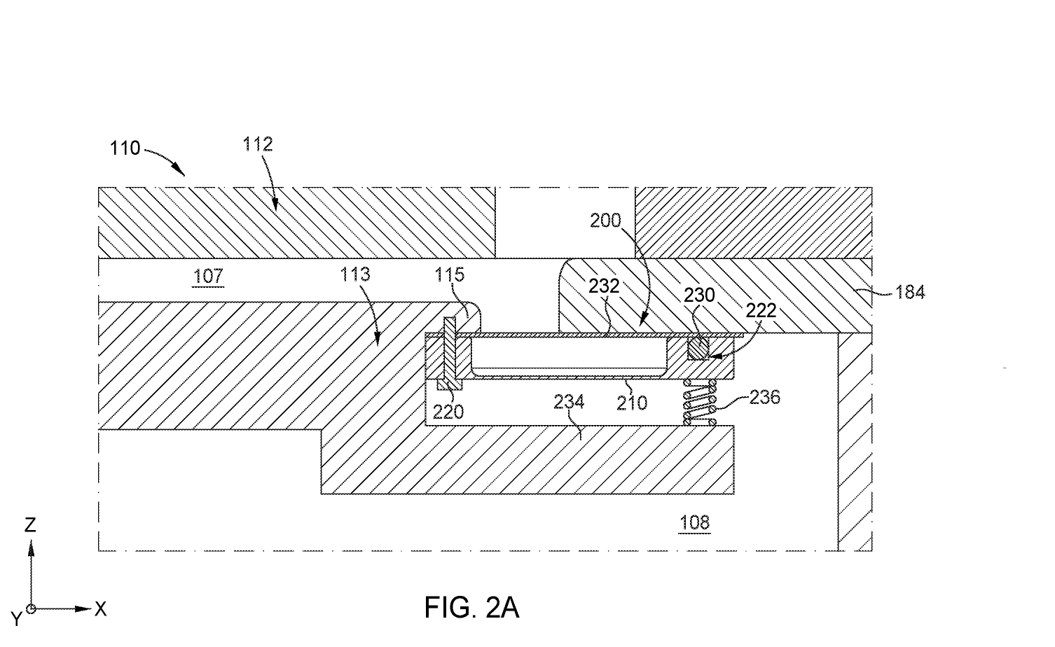

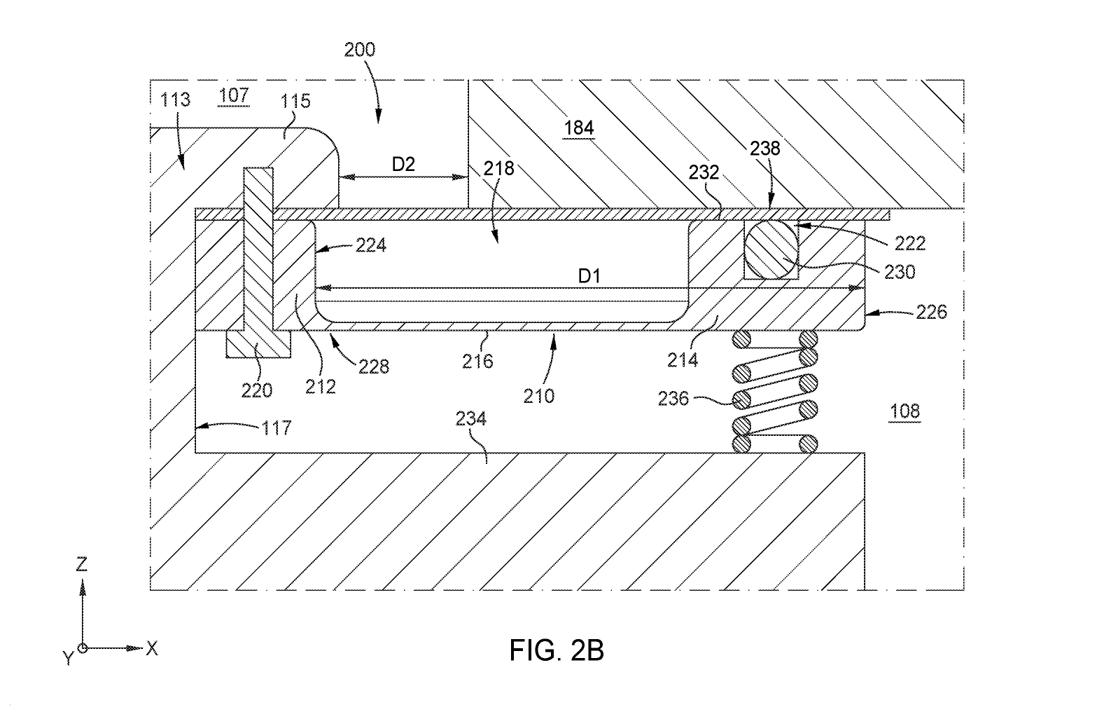

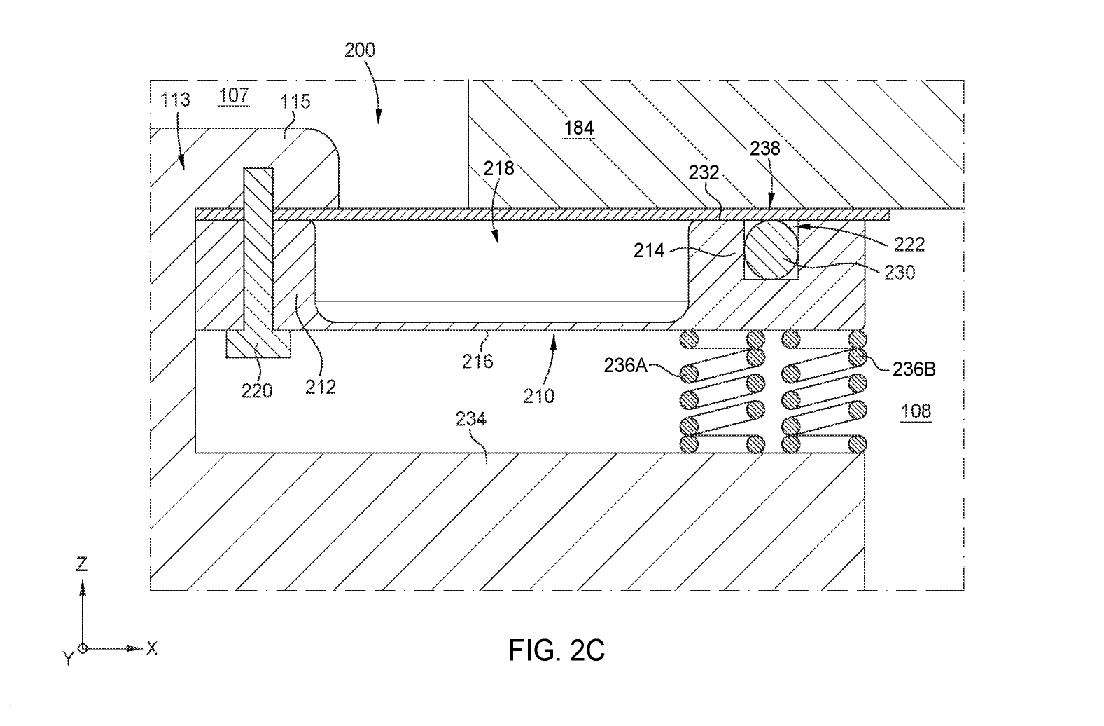

FIGS. 2A and 2B illustrate close-up, schematic cross-sectional views of the self-compliant seal assembly 200.

As depicted in FIGS. 2A and 2B, the self-compliant seal assembly 200 includes a compliant diaphragm 210 having an inner rim 212, an outer rim 214, and a base wall 216 extending between and connecting the inner rim 212 and the outer rim 214. The inner rim 212 is disposed radially inward of the outer rim 214 with respect to the central axis 114 (FIG. 1A). A diaphragm channel 218 is defined by the inner rim 212, the outer rim 214, and the base wall 216. The compliant diaphragm 210 can extend annularly around the central axis 114 (FIG. 1A). In this regard, the compliant diaphragm 210 can be a ring-shaped diaphragm. The compliant diaphragm 210 can contain, or be formed by, a metal (e.g., aluminum, hastelloy®, stainless steel (e.g., SS304 or SS316), etc.), or other spring-like materials. The compliant diaphragm 210 can be flexible so as to allow a range of distances extending along the Z-axis between the support plate 112 and the showerhead 140 (FIG. 1B) to be set, e.g., according to processing specifications, whilst still allowing the self-compliant seal assembly 200 to seal off the first region 107 from the second region 108 as will be further described below.

The inner rim 212 of the compliant diaphragm 210 can be coupled with the seal plate 113, e.g., by a plurality of circumferentially-spaced fasteners 220 (only one fastener is depicted in FIGS. 2A and 2B). Specifically, the inner rim 212 can be mechanically fastened to an upper flange 115 of the seal plate 113. The inner rim 212 is disposed, at least in part, underneath the upper flange 115. In some embodiments, an inner surface of the inner rim 212 engages, and is radially constrained by, a sidewall surface 117 of the seal plate 113. In other embodiments, the inner surface of the inner rim 212 can be radially spaced from the sidewall surface 117. The outer rim 214 is radially spaced from the inner rim 212 and is disposed, at least in part, underneath the pumping plate 184. The outer rim 214 forms a cavity 222. The cavity 222, like the diaphragm channel 218, can extend annularly. The cavity 222 is an open cavity and has an open upper end. While the cavity 222 is formed having a rectangular cross section in FIGS. 2A and 2B, in other embodiments, the cavity 222 can be formed by the outer rim 214 having other suitable cross-sectional profiles, such as a female dovetail profile, wherein the open upper end has a smaller radial length than does the closed lower end of the cavity 222.

In some embodiments, the compliant diaphragm 210 is arranged so that a radial distance D1 extending between an outer sidewall 224 of the inner rim 212 and an outer sidewall 226 of the outer rim 214 is between 20 mm to 35 mm, including the end points. In such embodiments, a radial gap between the upper flange 115 and the pumping plate 184 can be between 2 mm and 5 mm, including the end points. The compliant diaphragm 210 dimensioned in such a way can allow for the compliant diaphragm 210 to flex or deform elastically so as to allow a distance extending along the Z-axis between the support plate 112 and the showerhead 140 (FIG. 1B) to be adjustable or varied, e.g., according to processing specifications, whilst placing less than a threshold strain at an interface 228 between the inner rim 212 and the base wall 216.

A spring element 230 is disposed in the cavity 222. The spring element 230 can extend annularly along the cavity 222, for example. In this regard, the spring element 230 can be a ring-shaped spring element 230. The spring element 230 can contain, or be formed by, a metal (e.g., aluminum) or another electrically conductive, spring-like material. In at least some embodiments, the spring element 230 can be an RF gasket. In some embodiments, the spring element 230 can be rated to withstand operating temperatures of at least three hundred degrees Celsius (300° C). In yet other embodiments, the spring element 230 can be a spiral spring, a high temperature elastomer arranged to withstand temperatures above at least three hundred degrees (300° C), an L-shaped lip seal, or other bias components arranged to provide a positive bias. In at least some example embodiments, the spring element 230 is arranged to provide a positive bias between 0.5 mm to 1.5 mm, including the end points. While the spring element 230 has an oval-shaped cross section in FIGS. 2A and 2B, in other embodiments, the spring element 230 can have other suitable cross-sectional profiles.

The self-compliant seal assembly 200 also includes a compliant sheet 232 or foil. A radially inner portion of the compliant sheet 232 is disposed between the seal plate 113 and the inner rim 212. A radially outer portion of the compliant sheet 232 is disposed between the pumping plate 184 and the outer rim 214. Stated differently, a portion of the compliant sheet 232 is sandwiched between the seal plate 113 and the inner rim 212 and a portion of the compliant sheet 232 is sandwiched between the pumping plate 184 and the outer rim 214. The compliant sheet 232 can extend at least between the inner rim 212 and the outer rim 214, and can thus enclose the diaphragm channel 218. The compliant sheet 232 can contain, or be formed of, a metal (e.g., aluminum, stainless steel (e.g., SS304 or SS316), hastelloy®, etc.) or another compliant material. The compliant sheet 232 can be relatively thin and flexible, or stated differently, compliant so as to deform elastically or flex in the presence of a force. For instance, the spring element 230 can be arranged to positively bias the compliant sheet 232 against a lower surface of the pumping plate 184 to create a seal, as will be explained in further detail below. In some embodiments, the compliant sheet 232 can have a thickness of 100 microns to 300 microns, including the end points.

Further, in some embodiments, the seal plate 113 has an arm 234 with bias members 236 coupled thereto (only one bias member is shown in FIGS. 2A and 2B). The arm 234 can extend from a main body of the seal plate 113 and can be cantilevered as shown in FIGS. 2A and 2B. The arm 234 can extend annularly, and circumferentially-spaced bias members 236 can be arranged around the annulus (e.g., one bias member 236 per each hour on a clock face for twelve total bias members). In other embodiments, the arm 234 can include circumferentially-spaced segments that each extend from the main body and each segment can have one or more of the bias members 236 arranged at their respective distal ends. The arm 234 can extend a radial distance such that a portion of the arm 234 is radially aligned with the outer rim 214. In this way, a top end of each of the bias members 236 can engage a lower surface of the outer rim 214. In FIGS. 2A and 2B, the top end of the bias member 236 is shown engaging the lower surface of the outer rim 214. The bias members 236 can be mounted to an upper surface of the arm 234 (e.g., as illustrated in FIGS. 2A and 2B) or can be mounted within a recess defined by the upper surface. In some embodiments, the bias members 236 can contain, or be formed by, metal (e.g., stainless steel, hastelloy®, other nickel-based alloys, etc.). In at least some embodiments, the bias members 236 can be springs, such as compression springs, or other elements arranged to positively bias the outer rim 214 toward the pumping plate 184.

In some other embodiments, as depicted in FIG. 2C, multiple bias members can be aligned circumferentially along the arm 234 (e.g., two bias members 236 per each hour on a clock face for twenty-four total bias members). As illustrated in FIG. 2C, a first bias member 236A and a second bias member 236B are mounted to an upper surface of the arm 234 and are aligned circumferentially. In some embodiments, the first bias member 236A can be arranged, at least in part, radially inward of the spring element 230 and the second bias member 236B can be arranged, at least in part, radially outward of the spring element 230.

As shown in FIG. 1B and FIGS. 2A, 2B and 2C, when the substrate support 110 is in the raised position, the spring element 230 is arranged to positively bias the compliant sheet 232 toward the pumping plate 184 to form a compliant seal 238 that isolates the first region 107 from the second region 108 of the chamber volume 103 (FIG. 1A). When the compliant sheet 232 is positively biased by the spring element 230, e.g., in an upward direction along a Z-axis, the compliant nature of the compliant sheet 232 allows the compliant sheet 232 to “form to” or “mold to” any undulations in the pumping plate 184, which can result in an annular line contact for obtaining the compliant seal 238 in the chamber-in-chamber architecture. The compliant seal 238 can advantageously provide a symmetric RF return current path to the generators, which can lead to better process performance.

In some embodiments, the compliant seal 238 can allow for some leakage of gas between the first region 107 and the second region 108, e.g., so that a leak rate from one region to the other is under a predefined threshold, such as 200 mtorr/min, or can be hermetically sealed in some embodiments, e.g., so that fluid communication between the first region 107 and the second region 108 is prevented. In some embodiments, the spring element 230 can positively bias or project the compliant sheet 232 by 0.5 mm to 1.5 mm (including the end points), which can vary along the annulus of the compliant seal 238 due to undulations in the lower surface of the pumping plate 184. In this regard, with the positive bias provided by the spring element 230 and the flexible and compliant nature of the compliant sheet 232 (as well as the flexible and compliant nature of the compliant diaphragm 210), an annular compliant seal 238 can be achieved, even when such elements are formed of metal materials and even when the seal plate 113 is misaligned relative to the pumping plate 184, such as being tilted due to tolerance differences. Further, the bias members 236 can be arranged to bias the outer rim 214 toward the pumping plate 184. In this way, the outer rim 214, the spring element 230, and the compliant sheet 232 can be positively biased in an upward direction, e.g., along the Z-axis. In some embodiments, the bias members 236 can be aligned with the spring element 230 along a vertical axis, e.g., the Z-axis, which can concentrate the positive bias along the Z-axis. That is, a force stack up or positive bias stack up along the Z-direction can be achieved.

Moreover, because the components of the self-compliant seal assembly 200 are formed of relatively high temperature-resistant materials (e.g., materials able to withstand at least three hundred degrees Celsius (300° C)), higher operating temperature applications can be achieved. In addition, the flexible and compliant nature of the compliant diaphragm 210 can enable the capability to process the spacing and adjust the level of the support plate 112 (and consequently the substrate 155 (FIG. 1B) and the electrode 122 (FIG. 1B)) independently of the seal plate 113.

It is contemplated that any one or more elements or features of any one disclosed embodiment may be beneficially incorporated in any one or more other non-mutually exclusive embodiments. While the foregoing is directed to embodiments of the present disclosure, other and further embodiments of the disclosure may be devised without departing from the basic scope thereof, and the scope thereof is determined by the claims that follow.

What is claimed is:

1. A process station, comprising:
a chamber body defining a chamber volume;
a pumping plate disposed in the chamber body;
a substrate support disposed in the chamber body, the substrate support comprising:
a seal plate;
a self-compliant seal assembly, comprising:
a compliant diaphragm having an inner rim and an outer rim, the inner rim being coupled with the seal plate and the outer rim forming a cavity;
a spring element disposed in the cavity; and
a compliant sheet disposed between the seal plate and the inner rim and between the outer rim and the pumping plate,
wherein the spring element is arranged to bias the compliant sheet toward the pumping plate to form a compliant seal that isolates a first region from a second region of the chamber volume.

2. The process station of claim 1, wherein the seal plate has an arm with a bias member coupled thereto, and wherein the bias member mounted to the arm is arranged to bias the outer rim toward the pumping plate.

3. The process station of claim 2, wherein the bias member is aligned with the spring element along a vertical axis.

4. The process station of claim 1, wherein the compliant diaphragm is formed of metal.

5. The process station of claim 1, wherein the compliant sheet is formed of metal.

6. The process station of claim 1, wherein the spring element is a radio frequency (RF) gasket.

7. The process station of claim 1, wherein the compliant diaphragm and the compliant sheet are formed of at least one of: aluminum, stainless steel, or hastelloy.

8. The process station of claim 1, wherein the compliant diaphragm, the spring element, and the compliant sheet extend annularly around a central axis defined by the process station.

9. The process station of claim 1, wherein the compliant diaphragm is arranged so that a radial distance is between 20 mm to 35 mm, wherein the radial distance extends between an outer sidewall of the inner rim and an outer sidewall of the outer rim.

10. The process station of claim 9, wherein a radial gap between an upper flange of the seal plate and the pumping plate is between 2 mm and 5 mm.

11. The process station of claim 1, wherein the compliant sheet has a thickness of 100 microns to 300 microns.

12. The process station of claim 1, wherein the spring element is rated to withstand operating temperatures of at least three hundred degrees Celsius.

13. The process station of claim 1, wherein a fastener extends through the inner rim and the compliant sheet and into an upper flange of the seal plate.

14. The process station of claim 1, further comprising:
a support plate arranged above, and rigidly coupled with, the seal plate.

15. The process station of claim 1, wherein the seal plate has an arm with a bias member coupled thereto, and wherein the bias member mounted to the arm is arranged to bias the outer rim toward the pumping plate, and wherein the bias member is at least one spring arranged between the arm and the self-compliant seal assembly.

16. The process station of claim 1, wherein the spring element is a spiral spring.

17. A process station, comprising:
a radio frequency (RF) generator;
a chamber body defining a chamber volume;
a pumping plate disposed in the chamber body;
a substrate support disposed in the chamber body, the substrate support comprising:
a seal plate;
a self-compliant seal assembly, comprising:
a compliant diaphragm having an inner rim and an outer rim, the inner rim being coupled with the seal plate and the outer rim forming a cavity;
a spring element disposed in the cavity; and
a compliant sheet disposed between the seal plate and the inner rim and between the outer rim and the pumping plate,
wherein the spring element is arranged to bias the compliant sheet toward the pumping plate to form a compliant seal that isolates a first region from a second region of the chamber volume and forms a symmetric RF return path to the RF generator.

18. A self-compliant seal assembly for a process station, comprising:
a compliant diaphragm having an inner rim, an outer rim, and a base wall extending between and connecting the inner rim and the outer rim, wherein the outer rim defines a cavity and a diaphragm channel is defined between the inner rim and the outer rim;
a spring element disposed in the cavity; and
a compliant sheet contacting the inner rim and the outer rim, wherein the compliant sheet encloses the diaphragm channel and the spring element within the cavity.

19. The self-compliant seal assembly of claim 18, further comprising:
a bias member arranged to bias the outer rim toward the compliant sheet.

20. The self-compliant seal assembly of claim 18, wherein the spring element is formed of an electrically conductive material that is rated to withstand operating temperatures of at least three hundred degrees Celsius.
